(19) United States
(12) Patent Application Publication
(10) Pub. No.: US 2021/0229297 A1
(43) Pub. Date: Jul. 29, 2021

(54) CONVEYING HAND

(71) Applicant: KAWASAKI JUKOGYO KABUSHIKI KAISHA, Kobe-shi, Hyogo (JP)

(72) Inventors: Takeshi SHIBATA, Akashi-shi (JP); Yuya MUROI, Himeji-shi (JP)

(73) Assignee: KAWASAKI JUKOGYO KABUSHIKI KAISHA, Kobe-shi, Hyogo (JP)

(21) Appl. No.: 16/972,026

(22) PCT Filed: Jul. 1, 2019
(86) PCT No.: PCT/JP2019/026148

§ 371 Date: Dec. 4, 2020

(30) Foreign Application Priority Data
Jul. 9, 2018 (JP) 2018-130055

(51) Int. Cl. B25J 15/06; H01L 21/677

(52) U.S. Cl. CPC B25J 15/0683; H01L 21/677

(57) ABSTRACT

A conveying hand includes a hand body having a flat plate shape, with an opposing surface opposing to a workpiece, a communicating port to be connected to a fluid path opening in the opposing surface, an annular seat surrounding the periphery of the communicating port on the opposing surface and having a suction opening communicating with the communicating port, and a film part covering the communicating port and deformable according to a pressure of a fluid inside the fluid path. The film part is flat in a state where the fluid path is not decompressed, and is disposed on an extended line of the opposing surface, or at the suction opening side from the opposing surface.

### TECHNICAL FIELD

The present disclosure relates to a conveying hand which conveys a workpiece.

### BACKGROUND ART

As a conventional conveying hand, a general-purpose vacuum chuck disclosed in Patent Document 1 is known. In this general-purpose vacuum chuck, an upper plate, an air-chamber plate, a flexible thin film, and a chuck plate are laminated in this order. An exhaust and pressurizing port is provided to the upper plate, an air chamber is provided to the air-chamber plate, a suction opening is provided to the chuck plate, and these communicate with each other. Moreover, the flexible thin film has a hemispherical protrusion, which protrudes to the air-chamber side when discharging air (exhaust) and protrudes to the suction-opening side when pressurizing.

### REFERENCE DOCUMENT OF CONVENTIONAL ART

### Patent Document

### Patent Document 1: JP1998-044079A

### DESCRIPTION OF THE DISCLOSURE

### Problems to be Solved by the Disclosure

In the general-purpose vacuum chuck of Patent Document 1, since the flexible thin film has the hemispherical protrusion, it must have a large spacing between the flexible thin film and the exhaust and pressurizing port. Therefore, it takes time to pressurize and exhaust air in the space therebetween. In addition, it requires a large pressure for reversing the hemispherical protrusion between the exhaust and pressurizing port side and a suction opening side. Thus, it is inferior in the efficiency for sucking an object to be chucked on the suction opening.

The present disclosure is made in order to solve such problems, and one purpose thereof is to provide a conveying hand which can improve a suction efficiency.

### SUMMARY OF THE DISCLOSURE

A conveying hand according to one aspect of the present disclosure includes a hand body having a flat plate shape, with an opposing surface opposing to a workpiece. A communicating port to be connected to a fluid path opens in the opposing surface. The hand includes an annular seat surrounding the periphery of the communicating port on the opposing surface and having a suction opening communicating with the communicating port. The hand includes a film part covering the communicating port and deformable according to a pressure of a fluid inside the fluid path. The film part is flat in a state where the fluid path is not decompressed, and is disposed on an extended line of the opposing surface, or at the suction opening side from the opposing surface.

According to this structure, since the film part covering the communicating port is flat, the height of the seat surrounding the periphery of the communicating port can be lowered. Thus, the workpiece disposed on the seat can be brought closer to the communicating port so that a space between the film part and the seat can be reduced. Further, since the flat film part deforms more easily than a hemispherical protrusion, the pressure for deforming the film part can be reduced, and therefore, the efficiency for sucking the workpiece can be further improved.

The film part may be formed integrally with the seat. Thus, the film part and the seat can be made of the same material and formed in the same process, as a result, product and manufacturing cost can be reduced.

The seat may be comprised of an O-ring. Thus, for example, a commercially available O-ring can be used, as a result, the product and manufacturing cost can be reduced.

The seat may have a truncated cone shape so that a diameter increases as separating from the communicating port side. Thus, the film part can be closely contacted to the workpiece easily and the contact area therebetween can be increased. Therefore, sealability of the space between the film part and the workpiece is improved so that the workpiece is sucked more securely.

The seat may have an area of a base end on the opposing surface side equal to or more than an area of a tip end on the opposite side from the base end. Thus, the joining force between the seat and the hand body can be secured, deformation of the seat can be reduced, and the contact area with the workpiece can be reduced.

The seat may be formed integrally with the hand body. Thus, the seat and the hand body can be made of the same material and formed in the same process, as a result, the product and manufacturing cost can be reduced.

The workpiece may be a semiconductor substrate. Thus, since the communicating port to be connected to the fluid path is covered by the film part, it can be prevented that foreign matters (e.g., dust) are attached to the semiconductor substrate from the fluid path through the communicating port.

The conveying hand may be to convey the workpiece in a clean room. Thus, since the communicating port to be connected to the fluid path is covered by the film part, it can be prevented that foreign matters (e.g., dust) are discharged to a clean room.

### Effect of the Disclosure

The present disclosure can improve a suction efficiency of a conveying hand.

The above purpose, other purposes, features, and advantages of the present disclosure will be made clear from the following detailed description of suitable embodiments with reference to the accompanying drawings.

### BRIEF DESCRIPTION OF DRAWINGS

FIG. 1 illustrates a conveying hand according to Embodiment 1 of the present disclosure when seen from above.

FIG. 2 is a cross-sectional view illustrating a part of the conveying hand of FIG. 1.

FIG. 3(a) is a cross-sectional view illustrating a state where a workpiece is disposed on the conveying hand of FIG. 2.

FIG. 3(b) is a cross-sectional view illustrating a state where the workpiece of FIG. 3(a) is sucked.

FIG. 4 is a cross-sectional view illustrating a part of a conveying hand according to Embodiment 2 of the present disclosure.

FIG. 5 is a cross-sectional view illustrating a part of a conveying hand according to Embodiment 3 of the present disclosure.

FIGS. 6(a) and 6(b) are cross-sectional views illustrating a part of a conveying hand according to Embodiment 4 of the present disclosure.

### MODES FOR CARRYING OUT THE DISCLOSURE

Hereinafter, embodiments of the present disclosure will be described concretely with reference to the drawings. Note that, below, the same reference characters are given to the same or corresponding components throughout the drawings to omit redundant description.

### Embodiment 1

### <Configuration of Conveying Hand>

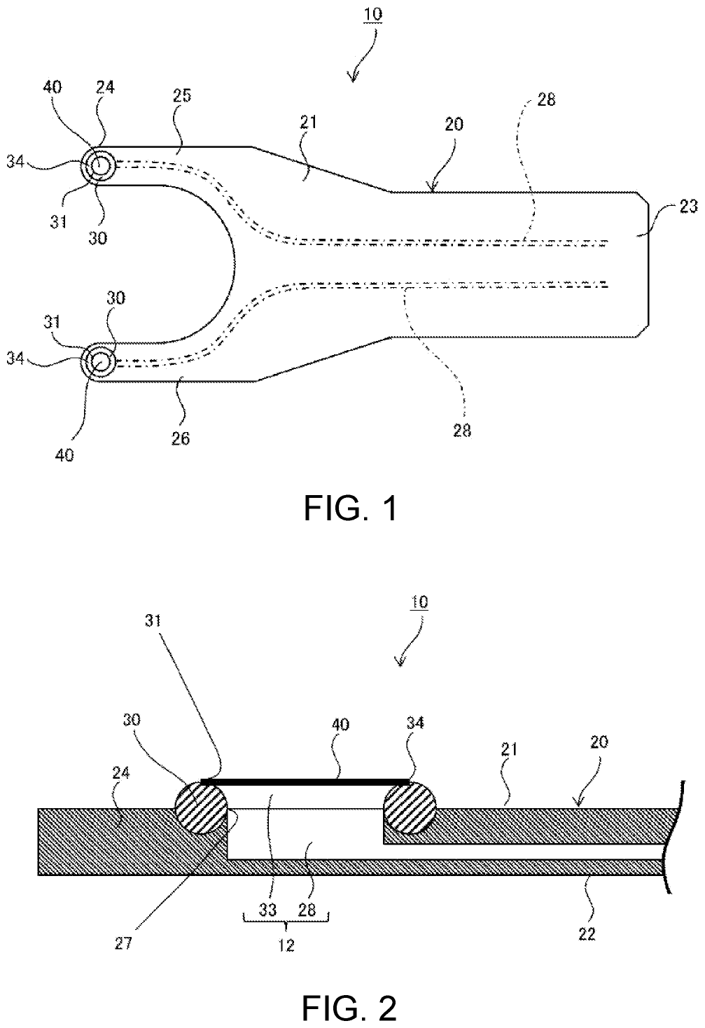

As illustrated in FIGS. 1 and 2, a conveying hand 10 according to one embodiment of the present disclosure is a hand for conveying a workpiece 11, such as a semiconductor substrate, and it is used by being attached to a conveying device, such as a robot. For example, it is used in a clean room where a high degree of cleanliness is required. Note that the degree of cleanliness can be expressed, for example, by the number of particles in 1 m³ of air in a form of exponent of ten.

The conveying hand 10 has a hand body 20, seats 30, and film parts 40. The hand body 20 is made of, for example, ceramic, resin, and elastic material, and is formed in a thin flat-plate shape, which has two flat surfaces perpendicular to a thickness direction. One of the flat surfaces (an opposing surface 21) opposes to the workpiece 11 placed on the conveying hand 10. Note that, below, although one side in a direction perpendicular to the opposing surface 21 (thickness direction) is referred to as “up or above” and the other side is referred to as “down or below,” the layout of the conveying hand 10 is not limited to this orientation. With this up-and-down direction, the opposing surface 21 is an upper surface of the hand body 20, and a surface opposite from the opposing surface 21 is a lower surface 22.

The hand body 20 has, for example, a Y-shape which branches into two from one end part 23 which is attached to the conveying device toward the other end part 24. Note that the shape of the hand body 20 is not limited to the Y-shape, and it may be other shapes, such as a rectangular shape and a circular shape.

Two branch parts (a first branch part 25 and a second branch part 26) extend from the one end part 23 side to the other end part 24 side in parallel to each other with a spacing therebetween. A communicating port 27 is provided to the other end part 24 of each of the first branch part 25 and the second branch part 26. Note that the number of communicating ports 27 in the conveying hand 10 is not limited to two, but may be one, or may be three or more. The plurality of communicating ports 27 are disposed so as to be separated from each other.

Each communicating port 27 has, for example, a circular shape and opens to the opposing surface 21, and it is connected to a fluid actuator (not illustrated) via a fluid path 28. The fluid path 28 is a path where fluid circulates, which extends in the hand body 20 from the one end part 23 to the other end part 24 and is connected to each communicating port 27. The fluid actuator (not illustrated) includes, for example, a pump and a cylinder. As the fluid, gas (e.g., air) or liquid (e.g., water) is used, for example.

The seat 30 is made of, for example, a sealant material which is sealable, and an O-ring is used for the seat 30. The seat 30 is flexible and made of an elastic material, such as resin (e.g., PTFE) or rubber.

The seat 30 has an annular shape, and, for example, has a ring shape or a cylindrical shape which protrudes from the opposing surface 21. The seat 30 has one end opening (upper opening 31), the other end opening (lower opening), and an interior space 33 between the upper opening 31 and the lower opening. For example, the upper opening 31 and the lower opening are provided to each seat 30.

The seat 30 is disposed on the opposing surface 21 of the hand body 20 so that it continuously surrounds the periphery of the communicating port 27. For example, the seat 30 is fitted in a dent of the hand body 20 formed around the communicating port 27.

The interior space 33 of the seat 30 has a substantially cylindrical shape, which extends in a direction perpendicular to the opposing surface 21 (up-and-down direction). The upper opening 31 and the lower opening of the seat 30 overlap with the communicating port 27 in the up-and-down direction so that the communicating port 27 is disposed between the upper opening 31 and the lower opening. Therefore, the interior space 33 is provided between the upper opening 31 and the communicating port 27 and communicates with the fluid path 28 through the communicating port 27. A total space 12, which is a combination of the interior space 33 and the fluid path 28 which communicate with each other, is formed.

The seat 30 has a cross-sectional area perpendicular to the up-and-down direction (the center axis of the seat 30) which becomes smaller from the opposing surface 21 side to the upper opening 31 side. The upper opening 31 disposed above the communicating port 27 is a suction opening which communicates with the communicating port 27, and, for example, it has a larger diameter than the communicating port 27. An annular upper end 34 of the seat 30 is provided to an outer circumference edge which surrounds the periphery of the upper opening 31.

The film part 40 is thin and has flexibility, and, for example, is made of an elastic material, such as resin (e.g., PTFE) or rubber. For example, the film part 40 has a disk shape, which spreads in a direction perpendicular to the up-and-down direction, and an outer circumference edge of the film part 40 is connected to the upper end 34 of the seat 30. Therefore, the film part 40 closes the upper opening 31 of the seat 30, above the opposing surface 21, and covers the communicating port 27 below the upper opening 31.

The film part 40 has no hole which communicates the interior space 33 with the exterior space. Therefore, the film part 40 seals the total space 12 including the interior space 33, and disconnects the total space 12 from the exterior space. The total space 12 is filled up with the fluid, and the film part 40 is deformable according to the pressure of the fluid inside the total space 12.

### <How to Use Conveying Hand>

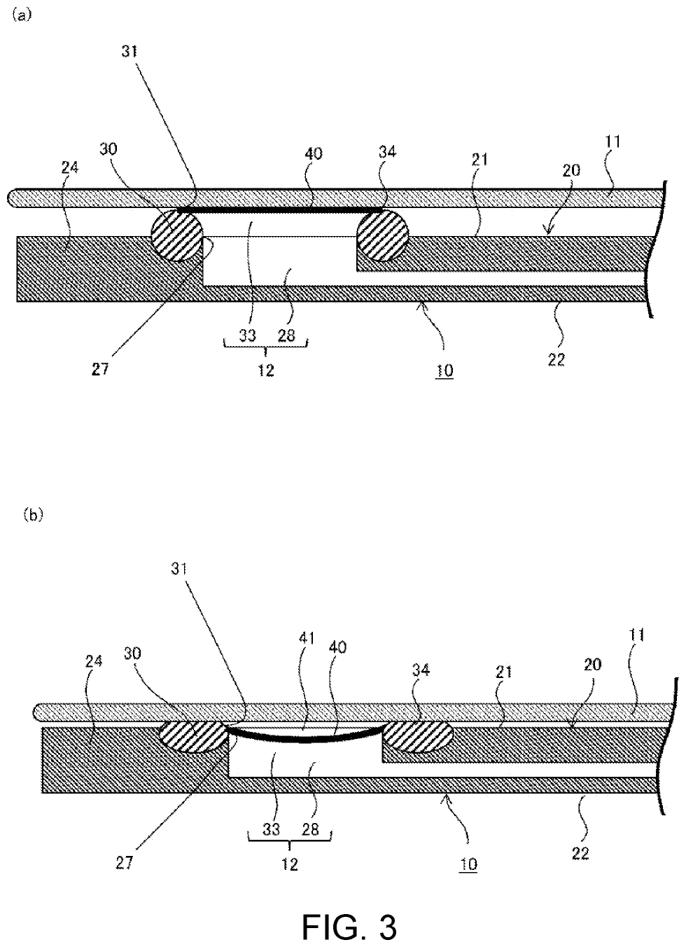

As illustrated in FIG. 3(a), when conveying the workpiece 11 by the conveying hand 10, the workpiece 11 is first placed on the opposing surface 21 of the conveying hand 10. Here, the workpiece 11 is disposed at the upper end 34 of the seat 30 which protrudes above the opposing surface 21. Therefore, the seat 30 having flexibility is deformed so as to conform to the shape of the workpiece 11, and the upper end 34 and/or the outer circumference edge of the film part 40 connected to the upper end 34 closely contacts the workpiece 11 to form a contacting part with the workpiece 11 therein.

Here, in a state where the fluid path 28 is not decompressed, the fluid actuator is controlled so that the film part 40 which closes the upper opening 31 of the seat 30 becomes flat. Therefore, the film part 40 conforms to the workpiece 11.

Then, the fluid actuator is operated so as to discharge the fluid from the interior space 33 of the seat 30. Thus, the fluid inside the interior space 33 is sucked to the fluid actuator side through the fluid path 28 so that the total space 12 including the fluid path 28 and the interior space 33 is decompressed.

Therefore, as illustrated in FIG. 3(b), the flexible film part 40 is deformed so that it is bent toward the communicating port 27 and the fluid path 28, and it separates from the workpiece 11 to form a space (film space 41) surrounded by the workpiece 11, the film part 40, and the seat 30. Since the pressure inside the film space 41 is below the atmospheric pressure, the workpiece 11 is sucked to the upper opening 31 of the seat 30 by the pressure difference.

Here, the seat 30 is deformed conforming to the shape of the workpiece 11 in connection with the deformation of the film part 40. Therefore, since the adhesion between the seat 30 and the workpiece 11 is maintained and airtightness of the film space 41 is secured, the workpiece 11 can be fully sucked and held. Moreover, since the plurality of seats 30 are provided in the conveying hand 10, the workpiece 11 can be conveyed while being held more securely. Moreover, since the workpiece 11 is disposed on the seat 30 which protrudes from the opposing surface 21, the contact area between the opposing surface 21 and the workpiece 11 can be reduced.

On the other hand, when removing the sucked workpiece 11, the fluid actuator is operated so that the fluid is supplied to the interior space 33 of the seat 30. Thus, the fluid flows into the interior space 33 from the fluid path 28 to increase the pressure inside the total space 12. Then, as illustrated in FIG. 3(a), the film part 40 which was curved downwardly is now deformed so that it resumes the flat state. Therefore, the pressure inside the film space 41 becomes equal to the atmospheric pressure, and the sucked workpiece 11 separates from the upper opening 31 of the seat 30.

Here, since the total space 12 is disconnected from the exterior space by the film part 40, the fluid supplied to the total space 12 will not be discharged to the exterior space. Therefore, even if the exterior space is a clean room, it can be prevented that the exterior space is contaminated by the fluid and foreign matters contained in the fluid.

Moreover, the film part 40 is disposed to the upper opening 31 side of the seat 30, from the opposing surface 21 side. Thus, the workpiece 11 placed on the upper end 34 of the seat 30 which surrounds the periphery of the upper opening 31 can be brought closer to the film part 40. Therefore, the film space 41 between the workpiece 11 and the film part 40 is small so that the efficiency for sucking the workpiece 11 is improved.

Moreover, in the state where the fluid path 28 is not decompressed, the film part 40 is flat. For example, like Patent Document 1, if the flexible thin film has the hemispherical protrusion, it will require a large pressure in order to deform the hemispherical protrusion. On the other hand, since the pressure for deforming the flat film part 40 can be reduced, the suction efficiency can be further improved.

Moreover, the hemispherical protrusion of the flexible thin film in Patent Document 1 only deforms into the shape protruded to the air-chamber side and the shape protruded to the opening side. Therefore, the pressure (sucking force) inside the space between the workpiece 11 and the flexible thin film cannot be adjusted arbitrarily. On the other hand, when deforming the flat film part 40, since the pressure inside the film space 41 between the workpiece 11 and the film part 40 is dependent on the amount of deformation of the film part 40, the pressure inside the film space 41 can be adjusted easily. Therefore, the deformation of the workpiece 11 can be prevented, without unintentionally large pressure acting on the workpiece 11 which is easy to be deformed.

Moreover, by using the O-ring as the seat 30, the product and manufacturing cost can be reduced. Moreover, in the opposing surface 21, the area of the seat 30 is larger than the area of the upper end 34 in the direction perpendicular to the up-and-down direction. Therefore, the joining force between the seat 30 and the hand body 20 can be secured, the deformation of the seat 30 can be reduced, and the contact area with the workpiece 11 can be reduced.

Moreover, an inner surface of the seat 30 is tapered so that its diameter increases to the upper opening 31 side from the communicating port 27 side. Therefore, the areas of the upper opening 31 and the film part 40 which covers the upper opening 31 can be increased so that the film part 40 is easily deformed, without increasing the outer diameter of the seat 30.

Note that the O-ring may be disposed on the opposing surface 21. Moreover, the seat 30 may have a rectangular shape or a trapezoidal shape in a cross section perpendicular to the circumferential direction.

### Embodiment 2

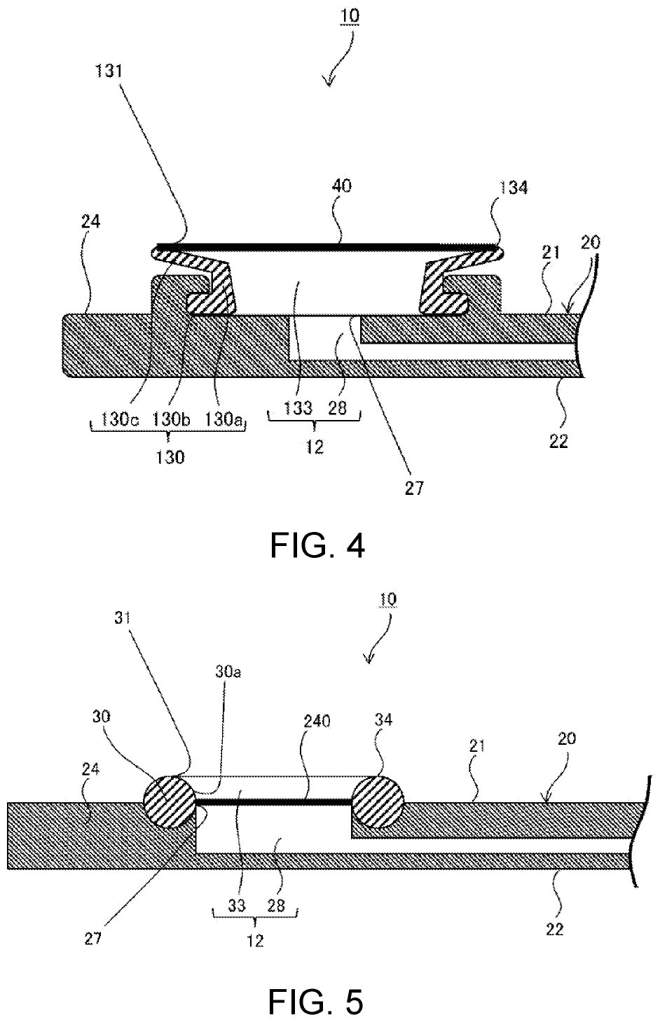

As illustrated in FIG. 4, the conveying hand 10 according to Embodiment 2 of the present disclosure differs from Embodiment 1 in the shape of a seat 130. Since other configurations are the same as Embodiment 1, description thereof is omitted.

The seat 130 has a cylindrical part 130a, a hook part 130b, and a diameter increased part 130c, and these are formed integrally. The hook part 130b has a flange shape which spreads radially outward from a lower end part of the cylindrical part 130a.

The cylindrical part 130a has one end opening (first upper opening), the other end opening (first lower opening), and a first interior space between the first upper opening and the first lower opening. A first inner circumferential surface which surrounds the first interior space increases in the diameter from the first lower opening toward the first upper opening, and a first outer circumferential surface of the cylindrical part 130a has a constant diameter in the up-and-down direction. Thus, the dimension (thickness) of the cylindrical part 130a between the first inner circumferential surface and the first outer circumferential surface is reduced from the first lower opening to the first upper opening.

The diameter increased part 130c has a truncated cone shape, and has one end opening (second upper opening 131, suction opening), the other end opening (second lower opening), and a second interior space between the second upper opening 131 and the second lower opening. The second lower opening is connected with the first upper opening of the cylindrical part 130a, and the first interior space communicates with the second interior space through the second lower opening and the first upper opening to form an interior space 133 of the seat 130.

In the diameter increased part 130c, a second inner circumferential surface which surrounds the second interior space, and a second outer circumferential surface which surrounds the second inner circumferential surface are increased in the diameters from the second lower opening toward the second upper opening 131. Therefore, the dimension (thickness) between the second inner circumferential surface and the second outer circumferential surface is constant from the second lower opening toward the second upper opening 131, and is thinner than the thickness of the cylindrical part 130a. Therefore, the diameter increased part 130c is easier to deform than the cylindrical part 130a.

The seat 130 is disposed on the opposing surface 21 of the hand body 20 so as to continuously surround the periphery of the communicating port 27. Thus, the first lower opening of the cylindrical part 130a of the seat 130 overlaps with the communicating port 27 in the up-and-down direction, and it is connected to the communicating port 27. Therefore, the interior space 133 communicates with the fluid path 28 through the communicating port 27 to form the total space 12 which is a combination of the interior space 133 and the fluid path 28 which communicate with each other.

The seat 130 is fitted in a dent of the hand body 20 where the hook part 130b is formed in the periphery of the communicating port 27, and is fixed to the hand body 20. The diameter increased part 130c is disposed above the opposing surface 21.

An outer circumferential end of the film part 40 is connected to an upper end 134 of the diameter increased part 130c which surrounds the periphery of the second upper opening 131. The film part 40 closes the second upper opening 131 at the second upper opening 131 side from the opposing surface 21, and covers the communicating port 27 therebelow. Thus, the film part 40 disconnects the interior space 133 of the seat 130 and the total space 12 including the interior space 133 from the exterior space.

When conveying the workpiece 11 by the conveying hand 10, the workpiece 11 is placed on the seat 130. Thus, the upper end 134 of the seat 130 closely contacts the workpiece 11, and the second upper opening 131 is covered by the workpiece 11. Then, when the total space 12 is decompressed by the fluid actuator, the film space 41 surrounded by the workpiece 11, the film part 40, and the seat 130 is formed, and the film space 41 is decompressed below the atmospheric pressure. Therefore, the workpiece 11 is sucked to the second upper opening 131.

Here, since the diameter increased part 130c is easy to deform along the shape of the workpiece 11, it can closely contact the workpiece 11 and can maintain the airtightness of the film space 41 so that the workpiece 11 can be fully sucked and held. Moreover, since the plurality of seats 130 are provided to the conveying hand 10, the workpiece 11 can be conveyed while being held more securely.

### Embodiment 3

As illustrated in FIG. 5, the conveying hand 10 according to Embodiment 3 of the present disclosure differs from Embodiment 1 in the position of a film part 240 with respect to the seat 30. Since other configurations are the same as Embodiment 1, description thereof is omitted.

An outer circumferential end of the film part 240 is connected with the inner circumferential surface 30a of the seat 30 which surrounds the periphery of the communicating port 27, and is disposed on an extended line of the opposing surface 21. Therefore, the film part 240 covers the communicating port 27 to disconnect the total space 12 from the exterior space.

When conveying the workpiece 11 by the conveying hand 10, the workpiece 11 is placed on the seat 30. Thus, the upper end 34 of the seat 30 closely contacts the workpiece 11, and the upper opening 31 is covered by the workpiece 11. Then, when the total space 12 is decompressed by the fluid actuator, the film space 41 surrounded by the workpiece 11, the film part 240, and the seat 30 is formed, and the film space 41 is decompressed below the atmospheric pressure. Therefore, the workpiece 11 is sucked to the upper opening 31.

The film part 240 is disposed on the extended line of the opposing surface 21. Therefore, the workpiece 11 placed on the upper end 34 of the seat 30 can be brought closer to the film part 240. Therefore, the film space 41 between the workpiece 11 and the film part 240 can be reduced, and the efficiency for sucking the workpiece 11 can be improved.

Moreover, the film part 240 is provided at the opposite side from the workpiece 11 with respect to the upper end 34 of the seat 30 which contacts the workpiece 11. Therefore, the contact area of the conveying hand 10 with the workpiece 11 can be reduced, without the film part 240 contacting the workpiece 11.

Note that, also in the seat 30 according to Embodiment 2, the film part 240 may be disposed on the extended line of the opposing surface 21 similar to Embodiment 3. Since the film space 41 can be reduced also in this case, the efficiency for sucking the workpiece 11 can be improved.

### Embodiment 4

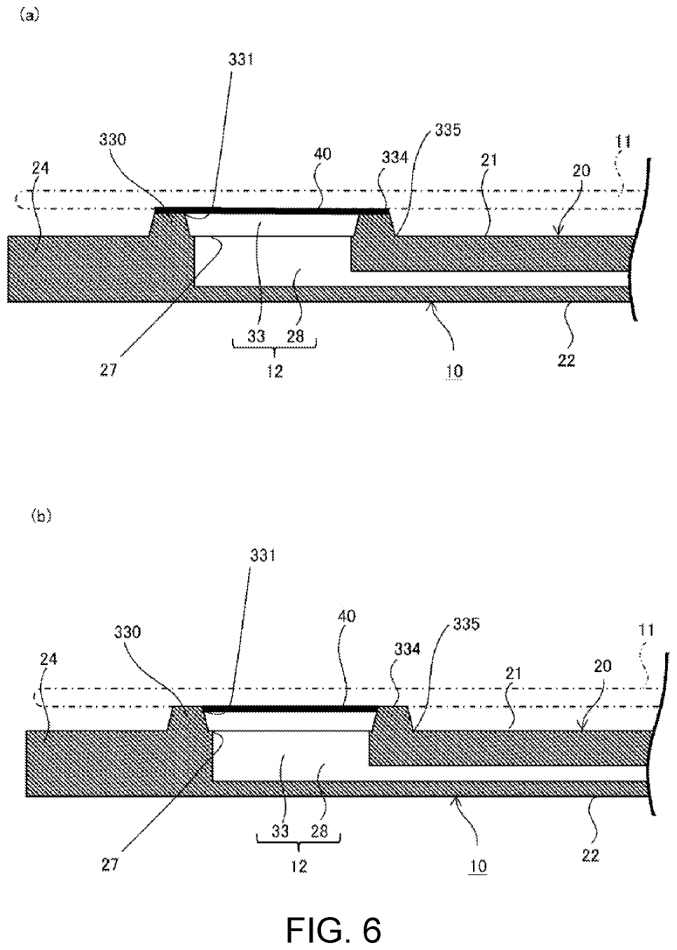

As illustrated in FIG. 6(a), the conveying hand 10 according to Embodiment 4 of the present disclosure differs from Embodiment 1 in the shape of the seat 130. Since other configurations are the same as Embodiment 1, description thereof is omitted.

A seat 330 has a cylindrical shape and its cross section perpendicular to the circumferential direction has a trapezoidal shape. Therefore, the seat 330 is formed so that an area of a base end 335 at the opposing surface 21 side of the hand body 20 is larger than an area of a tip end 334 (upper end) opposite from the base end 335. The deformation of the seat 330 can be reduced, and the contact area of the tip end 334 with the workpiece 11 disposed on the tip end 334 can be reduced. In addition, the height of the seat 330 can be lowered.

An inner surface of the seat 330 is tapered so that its diameter increases from the communicating port 27 side to an upper opening 331 side. Thus, the area of the upper opening 331 and the film part 40 which covers the upper opening 331 is increased without increasing the outer diameter of the seat 330, and thereby, the film part 40 is easier to deform.

The seat 330 is formed integrally with the hand body 20. According to this, since the same material is used for the seat 330 and the hand body 20, and they can be manufactured in the same process, the product and manufacturing cost can be reduced. Moreover, the joining strength between the seat 330 and the hand body 20 can be increased.

The film part 40 is connected to the seat 330 so as to cover the tip end 334 of the seat 330. Therefore, the film part 40 closes the upper opening 331 of the seat 330, above the opposing surface 21, and covers the communicating port 27 below the upper opening 331.

Moreover, since the tip end 334 of the seat 330 is covered by the film part 40, a part of the film part 40 which covers the tip end 334 contacts the workpiece 11. Therefore, since the seat 330 does not contact the workpiece 11, a degree of freedom in the material of the seat 330 can be increased. Note that the film part 40 may be attached to the seat 330 so that the tip end 334 of the seat 330 contacts the workpiece 11.

Alternatively, the seat 330 may be formed separately from the hand body 20, and may then be joined to the hand body 20. In this case, materials suitable for respective characteristics of the hand body 20 and the seat 330 can be selected, and therefore, a degree of freedom of such materials can be increased.

For example, ceramic with high rigidity may be used for the hand body 20, and an elastic material may be used for the seat 330. In this case, as illustrated in FIG. 6(b), the seat 330 can be deformed conforming to the shape of the workpiece 11 placed on the tip end 334 thereof and can closely contact the workpiece 11. Therefore, in this case, the film part 40 may connect the outer circumference edge to an inner circumferential surface of the seat 330, without covering the tip end 334 of the seat 330.

Moreover, the seat 330 may have a rectangular cross section perpendicular to the circumferential direction. Therefore, the seat 330 is formed so that the area at the base end 335 is equal to the area at the tip end 334. The deformation of the seat 330 can be reduced, and the contact area of the tip end 334 with the workpiece 11 disposed on the tip end 334 can be reduced. Moreover, the height of the seat 330 can be lowered, and the seat 330 can easily be formed.

In all the above embodiments, the film parts 40 and 240 may be formed integrally with the seats 30 and 130. In this case, the film parts 40 and 240 and the seats 30 and 130 are made of the same material and are formed in the same process. Therefore, the product and manufacturing cost can be reduced.

Moreover, in all the above embodiments, the film parts 40 and 240 may be provided at the upper openings 31, 131, and 331 side from the communicating port 27, as long as the film parts 40 and 240 cover the communicating port 27.

Note that all the above embodiments may be combined to each other unless one is to eliminate the other. Moreover, the above description is to be interpreted only as illustration, and the present disclosure is provided in order to teach the person skilled in the art the best mode to be implemented. The details of the configurations and/or the functions may be changed substantially, without departing from the spirit of the present disclosure.

### INDUSTRIAL APPLICABILITY

The conveying hand of the present disclosure is useful as the conveying hand which is improved in the suction efficiency.

### DESCRIPTION OF REFERENCE CHARACTERS

10: Conveying Hand
11: Workpiece
21: Opposing Surface
27: Communicating Port
30: Seat
31: Upper Opening (Suction Opening)
33: Interior Space
40: Film Part
130: Seat
131: Second Upper Opening (Suction Opening)
133: Interior Space
240: Film Part
330: Seat
331: Upper Opening (Suction Opening)

1. A conveying hand, comprising:
a hand body having a flat plate shape, with an opposing surface opposing to a workpiece, a communicating port to be connected to a fluid path opens in the opposing surface;
an annular seat surrounding the periphery of the communicating port on the opposing surface and having a suction opening communicating with the communicating port; and
a film part covering the communicating port and deformable according to a pressure of a fluid inside the fluid path,
wherein the film part is flat in a state where the fluid path is not decompressed, and is disposed on an extended line of the opposing surface, or at the suction opening side from the opposing surface.

2. The conveying hand of claim 1, wherein the film part is formed integrally with the seat.

3. The conveying hand of claim 1, wherein the seat is comprised of an O-ring.

4. The conveying hand of claim 1, wherein the seat has a truncated cone shape so that a diameter increases as separating from the communicating port side.

5. The conveying hand of claim 1, wherein the seat has an area of a base end on the opposing surface side equal to or more than an area of a tip end on the opposite side from the base end.

6. The conveying hand of claim 1, wherein the seat is formed integrally with the hand body.

7. The conveying hand of claim 1, wherein the workpiece is a semiconductor substrate.

8. The conveying hand of claim 1, wherein the conveying hand is to convey the workpiece in a clean room.
